(19) United States
(12) Patent Application Publication
(10) Pub. No.: US 2009/0170329 A1
(43) Pub. Date: Jul. 2, 2009

(54) PHOTO MASK

(75) Inventors: Sang Man BAE, Seoul (KR); Dong Heok Park, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-shi (KR)

(21) Appl. No.: 12/397,170

(22) Filed: Mar. 3, 2009

Related U.S. Application Data
(62) Division of application No. 11/270,464, filed on Nov. 10, 2005.

(30) Foreign Application Priority Data
Apr. 15, 2005 (KR) 10-2005-0031369

(51) Int. Cl. H01L 21/306

(52) U.S. Cl. 438/694; 257/E21.215

(57) ABSTRACT

A photo mask comprises a H-type light-shield pattern. In an exposure process, a photo mask is used to form a STAR (Step Asymmetry Recess) gate region, thereby stably securing a storage node contact region and improving a refresh characteristic of a semiconductor device.

### BACKGROUND OF THE INVENTION

1. Field of the Invention

The present invention generally relates to a photo mask, and more specifically, to a photo mask including a H-type light-shield pattern used in order to form a STAR gate region in an exposure process, thereby securing a storage node contact region and improving refresh characteristics of a semiconductor device.

2. Description of the Related Art

In general, due to high-integration of a semiconductor device, a gate having a stacked structure causes a problem such as a short channel effect.

In order to overcome the problem, a transistor having a Step Asymmetry Recessed (hereinafter, referred to as “STAR”) Cell Scheme has been suggested. The transistor having a STAR cell structure increases a channel length as a transistor having a structure where a step difference is formed in a gate region to overcome the short channel effect.

In one process for forming a STAR gate, a device isolation film defining an active region in a semiconductor substrate is formed, and then an additional etching mask pattern formed with a photo mask for forming a STAR gate is used in order to form a lower portion of a gate formed in the active region as a stair shape.

FIG. 1 is a plane view illustrating a conventional photo mask.

Referring to FIG. 1, a photo mask comprises a rectangular light-shield pattern 20 and a light-transmission pattern 30, wherein the rectangular light-shield pattern 20 is formed in a transparent substrate 10 in isolation and corresponds to a bit line contact region and a predetermined portion of the gate region adjacent to the bit line contact region in a semiconductor substrate, and elsewhere a transmission pattern 30.

FIG. 2 is a layout view illustrating a conventional semiconductor device.

Referring to FIG. 2, a photoresist film is formed on the entire surface of a semiconductor substrate 40 comprising a device isolation region 70 defining a G-type (galaxy type) or a T-type (letter ‘T’ type) active region. Then, an exposure and development process is performed via the photo mask of FIG. 1.

An etching mask pattern 50 formed by the exposure and development process is required to be rectangular to cover a center region of the active region 60, that is, a bit line contact region. However, when an excessive exposure process is performed to completely remove the residual photoresist film in other regions than the etching mask pattern 50, a corner of the etching mask pattern 50 is rounded and thus does not completely cover the active region 60.

Due to high integration of a semiconductor device, the etching mask pattern 50 becomes smaller to reduce adhesion to the semiconductor substrate 40. Moreover, an aspect ratio of the etching mask pattern 50 becomes higher to collapse the pattern.

As a result, a method for forming an etching mask pattern to form a STAR gate region as a line type has been suggested. Since a step difference is formed along the minor axis of the gate, the gate leans to a direction where the step difference is formed.

As described above, a STAR gate is formed to overcome the short channel effect. However, when the etching mask pattern for forming a STAR gate region is formed, an etching mask pattern is collapsed or a gate leaning phenomenon occurs to degrade refresh characteristics and reliability of the semiconductor device.

### SUMMARY OF THE INVENTION

Accordingly, it is an object of the present invention to provide a photo mask for forming a STAR gate region including a H-type light-shield pattern in an exposure process so as to prevent collapse of an etching mask pattern or a gate in a process for forming a STAR gate and secure a margin of the exposure process.

According to an embodiment of the present invention, a photo mask defining an etching mask pattern for formation of a STAR gate region comprising a bit line contact region and a predetermined portion of the gate region adjacent to the bit line contact region, the photo mask comprising a H-type light-shield pattern, wherein the H-type light-shield pattern comprises a first rectangular light-shield pattern covering at least the bit line contact region in an active region of the STAR gate region, and second light-shield patterns on a device isolation region adjacent to the both sides of the first light shield pattern, the second light-shield pattern disposed along with the major axis of the active region.

### BRIEF DESCRIPTION OF THE DRAWINGS

Other aspects and advantages of the present invention will become apparent upon reading the following detailed description and upon reference to the drawings in which:

FIG. 1 is a plane diagram illustrating a conventional photo mask;

FIG. 2 is a layout diagram illustrating a conventional semiconductor device;

FIG. 3 is a plane diagram illustrating a photo mask according to an embodiment of the present invention; and

FIGS. 4 and 5 are layout diagrams illustrating a semiconductor device according to an embodiment of the present invention.

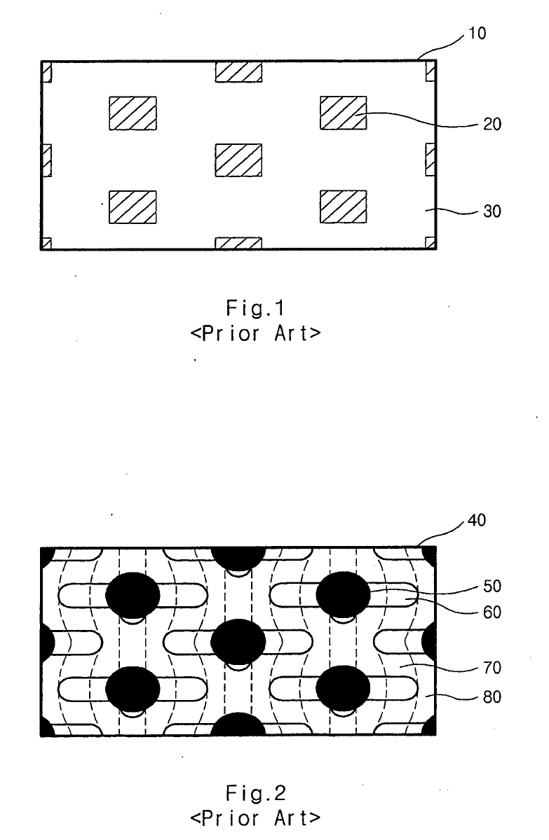

### DETAILED DESCRIPTION OF THE EXEMPLARY EMBODIMENTS

The present invention will be described in detail with reference to the accompanying drawings. Wherever possible, the same reference numbers will be used throughout the drawings to refer to the same or like parts. It should be appreciated that the embodiments are provided for the purpose that one ordinarily skilled in the art would be able to understand the present invention, and modifications in various manners and the scope of the present invention are not limited by the embodiments described herein.

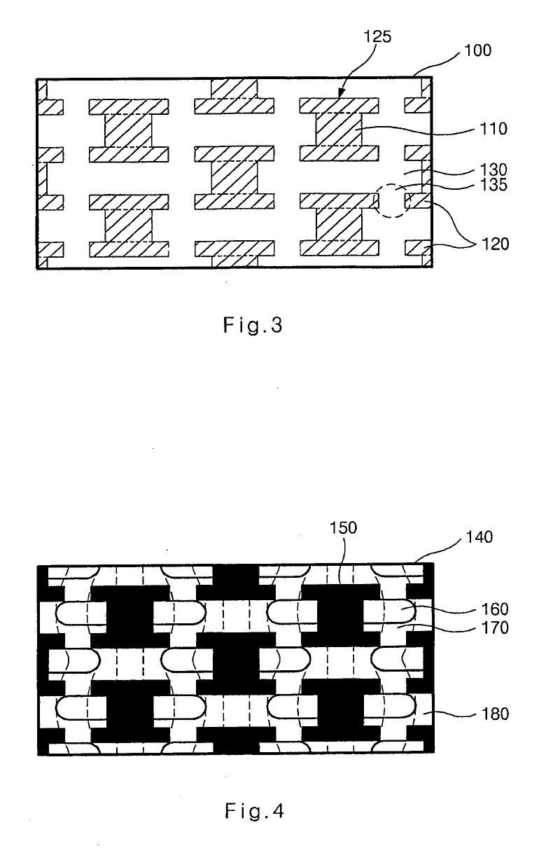

FIG. 3 is a simplified plane view illustrating a photo mask according to an embodiment of the present invention.

Referring to FIG. 3, the photo mask comprises a H-type light-shield pattern 125 and a light-transmission pattern 130, wherein the H-type light-shield patterns are alternately arranged on a transparent substrate 100, and elsewhere the light-transmission pattern 130. The H-type light-shield pattern 125 corresponds to an etching mask pattern on a semiconductor substrate (not shown), which is for formation of a STAR (Step Asymmetry Recess) gate region comprising a bit line contact region and a predetermined portion of the gate region adjacent to the bit line contact region in the semiconductor substrate having an active region and a device isolation film.

The H-type light-shield pattern 125 comprises a first light-shield pattern 110 covering the bit line contact region in an active region of the STAR gate region corresponding to a rectangular etching mask pattern, and second light-shield patterns 120 on a device isolation region adjacent to the both sides of the first light-shield pattern 110 are disposed along with a major axis of the active region. Here, the second light-shield pattern 120 corresponds to an etching mask pattern for covering the device isolation region adjacent to the rectangle etching mask pattern.

Preferably, the second light-shield pattern 120 is spaced apart from the neighboring second light-shield pattern 120 by a predetermined distance. Photoresist film patterns are formed on the semiconductor substrate corresponding to the predetermined distance between the neighboring second light-shield patterns 120, and the distance between two neighboring photoresist film patterns ranges from 30 to 110 nm, preferably. In addition, the distance between photoresist film patterns in an exposure process using KrF laser as a light source is less than 90 nm, and more preferably using ArF laser as a light source less than 70 nm.

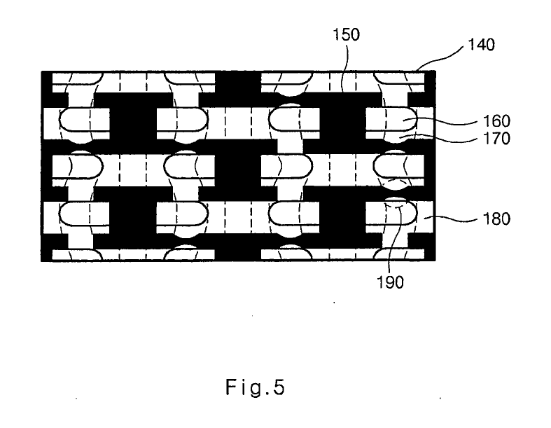

FIGS. 4 and 5 are layout views illustrating a semiconductor device in accordance with an embodiment of the present invention.

Referring to FIG. 4, an active region 160 and a device isolation region 170 are formed in a semiconductor substrate 140. Preferably, the device isolation region 170 is formed via STI (Shallow Trench Isolation) method, and the active region 160 is formed as one of a G-type or a T-type.

A H-type etching mask pattern 150 formed by the photo mask of FIG. 3 is disposed on a bit line contact region being a center region of the active region 160 and a predetermined portion of the gate region adjacent to the bit line contact region. Preferably, a predetermined region corresponding to the first light-shield pattern 110 of the H-type etching mask pattern 150 ranges from 10 to 50% of a region overlapped with the active region 160 and a gate 180.

In the exposure process for forming the H-type etching mask pattern 150, when a photoresist film on the semiconductor substrate 140 is exposed and developed with a light source having a proper energy, the H-type etching mask pattern 150 completely isolated as shown in FIG. 4 or the rectangular photoresist film pattern 150 having a sufficient corner can be left. As a result, a corner rounding phenomenon of the photoresist film pattern 150 is reduced to prevent the active region 160 from being exposed and the H-type etching mask pattern 150 to be collapsed.

Referring to FIG. 5, the H-type etching mask pattern 150 corresponding to the second light-shield pattern 120 of FIG. 3 is partially connected. The partial connection occurs by adjusting a space 135 between the neighboring second light-shield patterns 120. Here, the H-type etching mask pattern 150 is not formed as a complete isolation type but as a partially connected type so that the H-type etching mask pattern may be firmly fixed to the semiconductor substrate 140.

According to another embodiment of the present invention, a photo mask as shown in FIG. 3 is used, and a negative photoresist film is used as a photoresist film for forming a mask pattern to form a STAR gate region, so that the H-type etching mask pattern 150 is formed to have a pattern exposing the semiconductor substrate 140.

As described above, a photo mask according to an embodiment of the present invention is used to form a STAR gate region including a H-type light-shield pattern, thereby sufficiently securing a margin of an exposure process and preventing an etching mask pattern or a gate in a process for forming a STAR gate from being collapsed. As a result, a storage node contact region is stably secured, and a refresh characteristic of a semiconductor device is improved to obtain reliability.

The foregoing description of various embodiments of the invention has been presented for purposes of illustration and description. It is not intended to be exhaustive or to limit the invention to the precise form disclosed, and modifications and variations are possible in light of the above teachings or may be acquired from practice of the invention. Thus, the embodiments were chosen and described in order to explain the principles of the invention and its practical application to enable one skilled in the art to utilize the invention in various embodiments and with various modifications as are suited to the particular use contemplated.

1.-3. (canceled)

4. A method for fabricating a semiconductor device, the method comprising:
forming an active region and a device isolation region in a semiconductor substrate;
forming a photoresist film over the semiconductor substrate;
performing an exposure process using a photo mask including ‘H’ shaped patterns to thereby form rectangular photoresist patterns;
etching the active region and the device isolation region using the rectangular photoresist patterns as an etch mask to thereby form a step asymmetry recessed (STAR) region;
forming recessed gate patterns on the STAR region and the active region.

5. The method according to claim 4, wherein a bit line contact region is located between two recessed gate patterns on a single active region when the two recessed gate patterns intersect the single active region.

6. The method according to claim 5, wherein the photo mask defines the STAR regions, each STAR region comprising the bit line contact region and a predetermined portion of the gate region adjacent to the bit line contact region.

7. The method according to claim 6, wherein the predetermined portion ranges from 10% to 50% of an overlapped region between the gate region and the active region.

8. The method according to claim 6, wherein the photo mask comprises an H-type light-shield pattern comprising a first rectangular light-shield pattern covering at least the bit line contact region in the active region and second light-shield patterns on the device isolation region adjacent to two opposing sides of the first light shield pattern, the second light-shield patterns being disposed along a major axis of the active region.

9. The method according to claim 4, wherein a distance between two neighboring rectangular photoresist patterns ranges from 30 nm to 110 nm.

10. The method according to claim 4, wherein each ‘H’ shaped pattern in the photo mask is isolated.

11. The method according to claim 4, wherein two neighboring ‘H’ shaped patterns in the photo mask are partially connected.
